(19) United States
(12) Patent Application Publication
(10) Pub. No.: US 2026/0155816 A1
(43) Pub. Date: Jun. 4, 2026

(54) DUAL GATE CASCODE DRIVE

(71) Applicant: UNITED SILICON CARBIDE, INC., Princeton, NJ (US)

(72) Inventors: Anup Bhalla, Princeton, NJ (US); Xueqing Li, East Brunswick, NJ (US)

(73) Assignee: UNITED SILICON CARBIDE, INC., Princeton, NJ (US)

(21) Appl. No.: 18/706,401

(22) PCT Filed: Nov. 8, 2022
(86) PCT No.: PCT/US2022/049242

§ 371 Date: May 1, 2024

Related U.S. Application Data
(60) Provisional application No. 63/276,747, filed on Nov. 8, 2021.

(51) Int. Cl. H03K 17/081; H03K 17/041

(52) U.S. Cl. CPC H03K 17/08104; H03K 17/04106

(57) ABSTRACT

A cascode circuit is formed using a high voltage transistor in series with a low voltage transistor. A clamp switch device is used to discharge the gate of the high voltage transistor when the cascode is off. Rate limiting devices may be used control turn on and turn off characteristics of the cascode. Rate limiting devices may be include resistors and/or transistors. The high voltage transistor may be a normally on silicon carbide JFET, for example, and the low voltage transistor may be a silicon MOSFET.

### TECHNICAL FIELD

This disclosure pertains to high power and high voltage cascode circuits.

### BACKGROUND

U.S. Pat. No. 9,048,119 (Kanazawa, et al.) Semiconductor device with normally off and normally on transistors, granted Jun. 2, 2015, describes how a cascode semiconductor device with a normally-on silicon carbide (SiC) JFET and a normally-off silicon (Si) MOSFET may be damaged by current flows in certain modes of operation, and that such damage may be mitigated in a scheme whereby the normally-on SiCJFET and the normally-off Si-type MOSFET are controlled so as to have a period in which both transistors are set in an OFF state.

FIG. 1 is an electrical schematic diagram of a prior art cascode circuit using the Infineon 1EDI30J12Cx driver. The cascode circuit includes a low voltage silicon p-channel MOSFET connected in series with a normally-on SiC JFET. In the example of FIG. 1, the MOSFET and JFET are discrete devices coupled to separate specialized driver outputs of a single driver integrated circuit.

FIG. 2 is an electrical schematic of a prior art Texas Instruments “safety cascode” device. In the example of FIG. 2, a low-voltage n-channel silicon MOSFET is incorporated in a driver chip. The MOSFET is enabled when the device is active. To control conduction through the drain of the device, a depletion mode a gallium nitride (GaN) HEMT is then switched directly. The HEMT is co-packaged with the driver chip to minimize inductances and provide fast switching.

FIGS. 3 and 4 are taken from U.S. Pat. No. 9,083,343 (Li, et al.) Cascode Switching circuit, granted Jul. 14, 2015. FIG. 3 shows a gate drive scheme for a device where gates of a JFET and a MOSFET are controlled separately with a single drive IC. This technique does require the creation of two different gate pulses by the gate drive circuit. FIG. 4 illustrates signals that may be used for cascode operation of the JFET and MOSFET.

FIG. 5 shows a prior art circuit using an Infineon 1ED3451M gate drive IC to drive an IGBT. The CLAMPDRV signal from the IC drives an external Miller Clamp transistor. This transistor is used to shunt the gate of the IGBT while it is in the off state.

When the device is in the off state, a high dV/dt at the collector (or drain) can cause a displacement current through the capacitance from gate to drain, Cgd, (Miller capacitance), high enough to develop a voltage drop across the turn-off gate resistor to turn-on the device. To prevent this, the gate resistor can be shunted by the MOSFET driven by the output of the CLAMPDRV pin. This pin is designed to keep the clamping MOSFET on whenever the main power IGBT is off.

### SUMMARY

Embodiments of a cascode circuit are shown. In some embodiments, the cascode circuit includes a junction field-effect transistor (JFET) having a JFET drain, a JFET source, and a JFET gate. The JFET drain is connected to a drain of the cascode circuit, wherein the JFET is a normally-on n-type silicon carbide JFET. The cascode circuit further includes a metal-oxide-semiconductor field-effect transistor (MOSFET) that includes a MOSFET drain, a MOSFET source, and a MOSFET gate. The MOSFET drain is connected to the JFET source and the MOSFET source is connected to a source of the cascode circuit. The MOSFET is a normally off n-type silicon MOSFET. A driver circuit provides outputs that include a first cascode gate signal and a clamp signal. In some embodiments, the cascode gate signal and clamp signal are complementary waveforms, wherein the first cascode gate signal is received by the gate of the MOSFET. A clamp switch is controlled by the clamp signal, wherein the clamp switch, when activated, connects the gate of the JFET to the source of the cascode circuit. In a first mode, the first cascode gate signal causes the MOSFET to conduct and current flows from the drain of the cascode circuit to the source of the cascode circuit via the JFET and the MOSFET while the clamp switch is off. In a second mode, the clamp signal causes the clamp switch to connect the JFET gate to the MOSFET source when the clamp switch is on.

In some embodiments, a cascode circuit, includes: a junction field-effect transistor, JFET, includes a JFET drain, a JFET source, and a JFET gate, the JFET drain being connected to a drain of the cascode circuit, wherein the JFET is a normally-on n-type silicon carbide JFET; a metal-oxide-semiconductor field-effect transistor, MOSFET, includes a MOSFET drain, a MOSFET source, and a MOSFET gate, the MOSFET drain being connected to the JFET source and the MOSFET source being connected to a source of the cascode circuit, wherein the MOSFET is a normally-off n-type silicon MOSFET; a driver circuit providing outputs includes a first cascode gate signal and a clamp signal, the first cascode gate signal and the clamp signal being complementary waveforms, wherein the first cascode gate signal is connected to the MOSFET gate; and a clamp switch controlled by the clamp signal, wherein the clamp switch, when activated, connects the JFET gate to the source of the cascode circuit; whereby in a first mode the first cascode gate signal causes the MOSFET to conduct and current flows from the drain of the cascode circuit to the source of the cascode circuit via the JFET and the MOSFET while the clamp switch is off, and in a second mode, the clamp signal causes the clamp switch to connect the JFET gate to the MOSFET source when the first cascode gate signal is off. In some embodiments, the first cascode gate signal is connected directly to the MOSFET gate. In some embodiments, a first rate-control device connects the JFET gate to the source of the cascode circuit. In some embodiments, the first rate-control device includes a first resistor. In some embodiments, the first rate-control device includes a first transistor. In some embodiments, the clamp switch is connected to the JFET gate via a second rate-control device. In some embodiments, the second rate-control device includes a second resistor. In some embodiments, the second rate-control device includes a second transistor. In some embodiments, the driver circuit further provides a second cascode gate signal, the second cascode gate signal being connected to the JFET gate. In some embodiments, the second cascode gate signal is connected to the MOSFET gate via a third rate-control device.

In some embodiments, a cascode circuit, includes: a junction field-effect transistor, JFET, includes a JFET drain, a JFET source, and a JFET gate, the JFET drain being connected to a drain of the cascode circuit, wherein the JFET is a normally-on n-type silicon carbide JFET; a metal-oxide-semiconductor field-effect transistor, MOSFET, includes a MOSFET drain, a MOSFET source, and a MOSFET gate, the MOSFET drain being connected to the JFET source and the MOSFET source being connected to a source of the cascode circuit, wherein the MOSFET is a normally-off n-type silicon MOSFET; connectors receiving driver circuit outputs includes a first cascode gate signal and a clamp signal, the first cascode gate signal and the clamp signal being complementary waveforms, wherein the first cascode gate signal is connected to the MOSFET gate; and a clamp switch controlled by the clamp signal, wherein the clamp switch, when activated, connects the JFET gate to the source of the cascode circuit; whereby in a first mode the first cascode gate signal causes the MOSFET to conduct and current flows from the drain of the cascode circuit to the source of the cascode circuit via the JFET and the MOSFET while the clamp switch is off, and in a second mode, the clamp signal causes the clamp switch to turn on and short the JFET gate to the MOSFET source. In some embodiments, the first cascode gate signal is connected directly to the MOSFET gate. In some embodiments, a first rate-control device connects the JFET gate to the source of the cascode circuit. In some embodiments, the first rate-control device includes a first resistor. In some embodiments, the first rate-control device includes a first transistor. In some embodiments, the clamp switch is connected to the JFET gate via a second rate-control device. In some embodiments, the second rate-control device includes a second resistor. In some embodiments, the second rate-control device includes a second transistor. In some embodiments, the driver circuit outputs further provide a second cascode gate signal, the second cascode gate signal being connected to the JFET gate.

In some embodiments, a cascode circuit, includes: a depletion mode field-effect transistor (FET) having a first drain, a first source, and a first gate; a enhancement mode FET having a second drain, a second source, and a second gate, wherein the first source is connected to the second drain; and a clamping device having a first clamping terminal connected to the first gate and a second clamping terminal connected to the second source.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to limitations that solve any or all disadvantages noted in any part of this disclosure.

### BRIEF DESCRIPTION OF THE DRAWINGS

A more detailed understanding may be had from the following description, given by way of example in conjunction with the accompanying drawings.

FIGS. 1-5 are electrical schematics of prior art cascode circuits.

FIG. 6 is a circuit diagram of a cascode circuit, in accordance with some embodiments.

FIG. 7 is a circuit diagram of a cascode circuit, in accordance with some embodiments.

FIG. 8 is a circuit diagram of a cascode circuit, in accordance with some embodiments.

FIG. 9 is a circuit diagram of a cascode circuit, in accordance with some embodiments.

FIG. 10 shows the cascode circuit of FIG. 9 along with waveforms for the gate signal and waveforms for the clamp drive signal, in accordance with some embodiments.

FIG. 11A illustrates a current and voltage graph versus time of the cascode circuit in FIG. 10, in accordance with some embodiments.

FIG. 11B illustrates a current and voltage graph versus time of the cascode circuit in FIG. 6, in accordance with some embodiments.

FIG. 12 is an embodiment of a cascode circuit 700 in accordance with some embodiments.

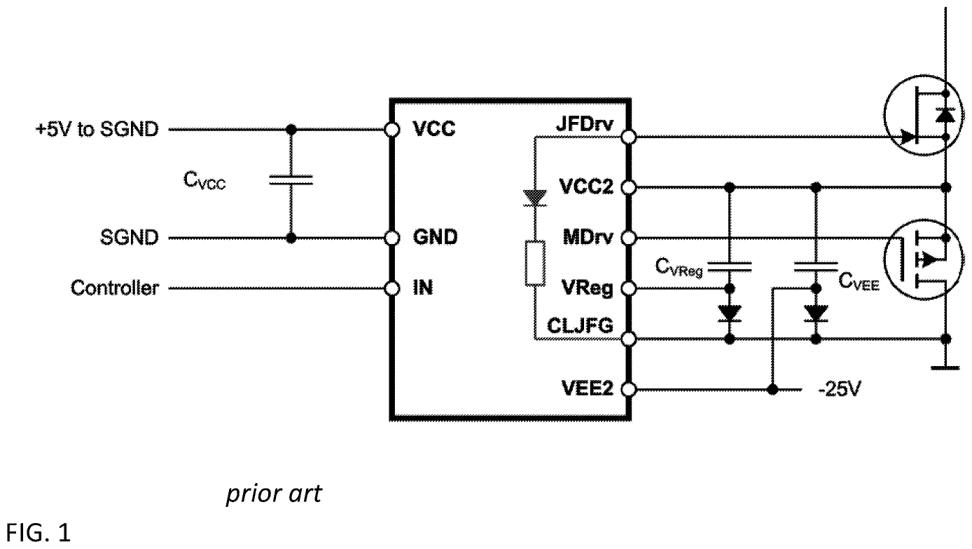

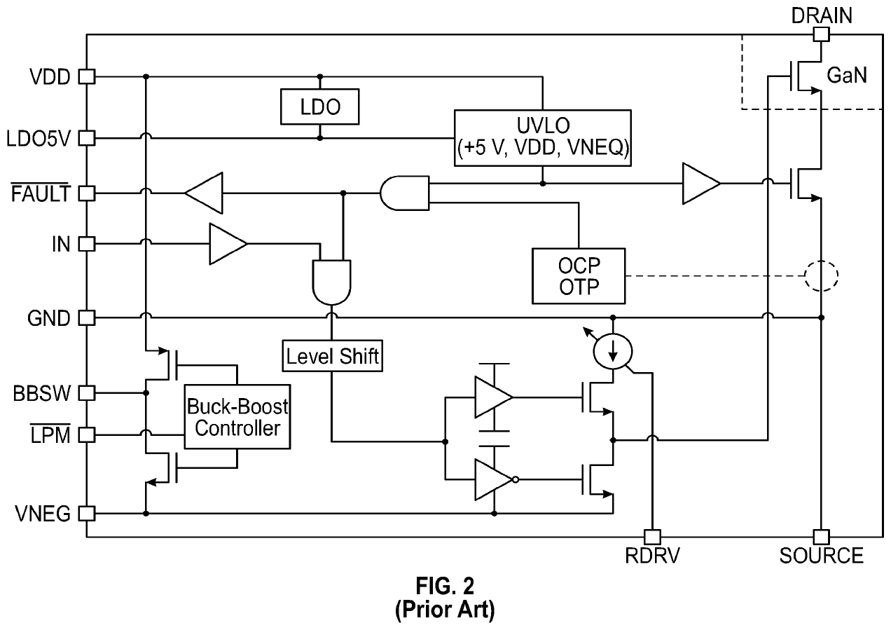

### DETAILED DESCRIPTION

Cascode circuits may be implemented with a wide variety of devices and device combinations. For purposes of illustration, examples herein often refer to specific combinations of high voltage and low voltage device types and specific combinations of enhancement mode and depletion mode devices. It will be appreciated that the techniques described herein may equally be applied to a range of MOSFET, JFET, BJT, IGBT, thyristor, and other devices in a wide range of combinations.

In a cascode circuit, the gate of the high voltage depletion mode transistor is connected to the source of the low voltage enhancement mode transistor. Driving the gates separately in a “dual gate” configuration allows opportunities for better control over switching characteristics of the cascode circuit. As explained in further detail below, the cascode circuit is turned off by first turning off the low voltage enhancement mode transistor, allowing its drain voltage to rise. The drain of the low voltage transistor is tied to the source of the high voltage depletion mode transistor source. Since the gate of the high voltage depletion mode transistor is connected to the source of the low voltage enhancement mode transistor, a negative voltage appears from the gate to the source of the depletion mode transistor thereby turning off the depletion mode transistor. Configurations that allow for separate-control of the depletion mode and enhancement mode transistors using dual gates allow for flexible switching speed control through the use of simple rate-control devices such as resistors, transistors, capacitors, and/or combinations thereof, as described below.

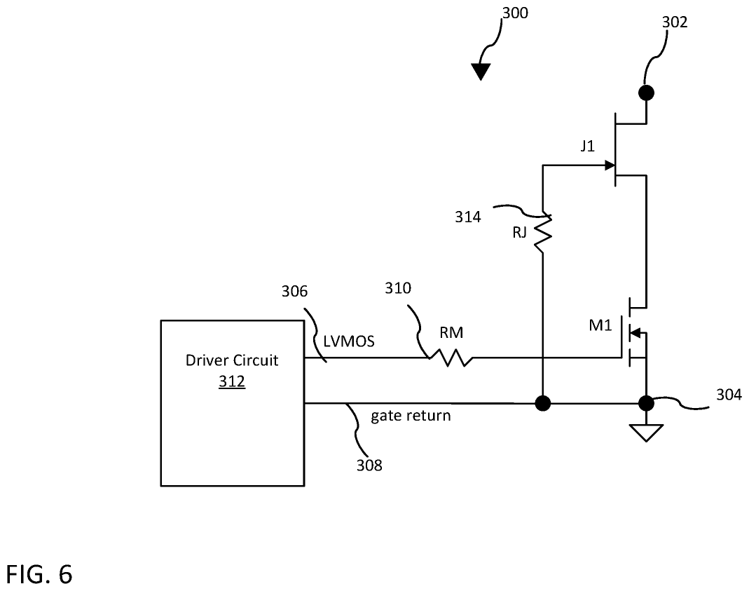

FIG. 6 is a circuit diagram of a cascode circuit 300, in accordance with some embodiments.

In FIG. 6, the cascode circuit 300 includes a high-voltage n-type JFET J1, a low-voltage n-type MOSFET M1, a connection terminal 302, a connection terminal 304, a control terminal 306, and a gate return terminal 308. In some embodiments, the connection terminal 302 is the drain of the cascode circuit 300. In some embodiments, the connection terminal 304 is the source of the cascode circuit 300. In some embodiments, the control terminal 306 is the gate of the cascode circuit 300.

The JFET J1 is connected in cascode with a the MOSFET M1. In some embodiments, the JFET J1 and the MOSFET M1 are connected in a half-bridge configuration. The JFET J1 is a normally on field effect transistor (FET). A normally on FET is a depletion mode FET. A normally on FET (i.e., a depletion mode FET) is a FET that remains on when a non-negative voltage is seen between the gate and the source of the FET. Thus, when zero volts is seen between the gate and the source of the FET, the JFET J1 remains on. To turn off the JFET J1 a negative voltage with a magnitude at a turn off voltage level has to be applied from the gate to the source. The MOSFET M1 is a normally off field effect transistor (FET). A normally off FET is an enhancement mode FET. A normally off FET (i.e., an enhancement mode FET) is a FET is off when zero volts is seen between the gate and the source of the FET.

In FIG. 6, a drain of the JFET J1 is connected to the connection terminal 302, a source of the JFET J1 is connected to the drain of the MOSFET M1, and a source of the MOSFET M1 is connected to the connection terminal 304. In FIG. 6, the connection terminal 304 is connected to ground. When both the JFET J1 and the MOSFET M1 are turned on, the JFET J1 and the MOSFET M1 are both in a low resistance state and current is allowed to flow from the terminal 302 to the terminal 304. When both the JFET J1 and the MOSFET M1 are turned off, both of the JFET J1 and the MOSFET M1 are in a high resistance state and current is blocked (other than leakage current) from passing from the terminal 302 to the terminal 304.

In this embodiment, the gate return terminal 308 is directly connected to the connection terminal 304, which is directly connected to ground. A gate of the JFET J1 is coupled to the connection terminal 304. However, a first rate-control device 310 is connected in series between the gate of the MOSFET M1 and the control terminal 306. A driver circuit 312 is configured to generate a low-voltage MOS gate signal LVMOS. In response to the gate signal LVMOS being in a high voltage state, the MOSFET M1 is turned on. Since the gate of the JFET J1 is connected to ground (i.e., a non-negative voltage), the JFET J1 is also turned on. As such, the cascode circuit 300 allows current to pass from the connection terminal 302 to the connection terminal 304. To turn off the cascode circuit 300, the gate signal LVMOS is provided in a low voltage state (e.g., ground). Accordingly, the MOSFET M1 is turned off. However, since the JFET J1 is a normally on FET, the JFET J1 remains on. Voltage thus builds up at the source of the JFET J1 and the drain of the MOSFET M1. Thus, a negative voltage appears from the gate (which is tied to ground) to the source of the JFET J1 (where charge is building up). Once the negative voltage reaches the turn off voltage level, the JFET J1 turns off.

To control how fast the cascode circuit 300 is turned on and turned off, the first rate-control device 310 and a second rate-control device 314 are provided in the cascode circuit 300. The rate-control devices 310, 314 slow down the charging and discharging of the gates of the JFET J1 and the MOSFET M1, thereby allowing the turn on and turn off speed of the cascode circuit 300 to be predetermined by design. In this example, the first rate-control device 310 is a simple resistor with a resistance of RM. In other embodiments, the first rate-control device 310 is formed from one or more resistors, transistors, capacitors, and/or combinations thereof.

The driver circuit 312 is a drive IC, in accordance with some embodiments. In the example of FIG. 6, the driver circuit 312 provides a gate return path through the gate return terminal 308 from the source of the MOSFET M1.

The second rate-control device 314 is connected in series is connected in series between the gate of the JFET J1 and the connection terminal 304. In this embodiment, the second rate-control device 314 is a resistor that has a resistance of RJ, connecting the gate of the JFET J1 to the source of the MOSFET M1. The rate-control devices 310, 314 are configured to slow down the switching slew rates. Notably, the rate-control device 314, controls the overall device speed and is not connected to the control terminal 306.

In some embodiments, the second rate-control device 314 impacts the diode recovery process. For example, during freewheeling operation, current may flow in the body diode of the MOSFET M1. If the gate of the JFET J1 is shorted to the source of the MOSFET M1, the JFET J1 is on. In a typical inductive load circuit, when the body diode of the MOSFET M1 turns off, the MOSFET M1 recovers before the JFET J1. As voltage across the MOSFET M1 rises, the drain-to-source voltage (Vds) of the MOSFET M1 acts as a negative gate drive voltage on the JFET J1, as explained above. As a result, the JFET J1 begins to turn-off. However, the second rate-control device 314 slows down how fast the JFET J1 turns off, causing a period where the recovery current passing through the JFET J1 rises because the JFET J1 does not turn off fast enough. In some embodiments, this increases the amount of power dissipated in the cascode before the JFET turns off, thereby creating turn-on efficiency losses.

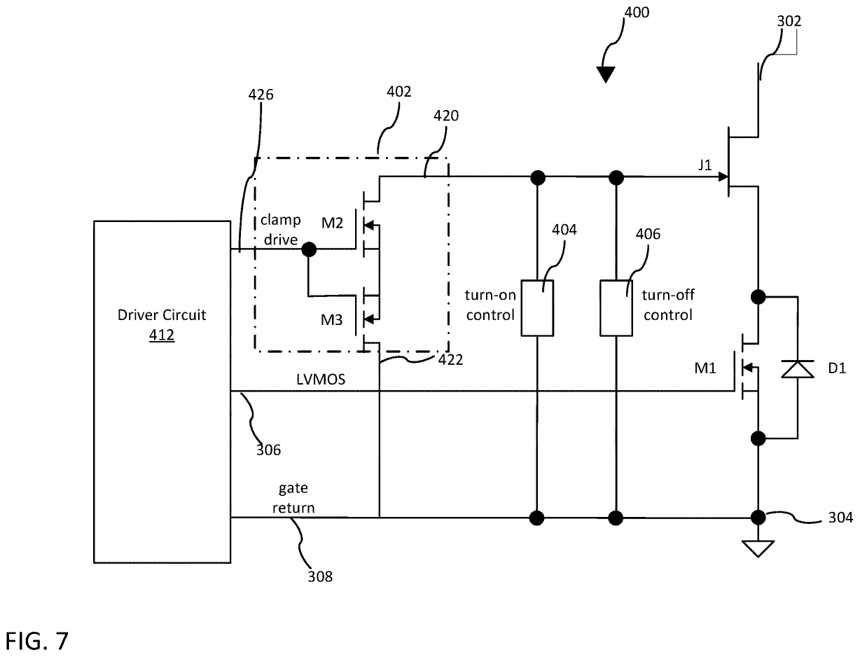

FIGS. 7-10 illustrate additional cascode circuits which address this challenge while still providing good control of the switching slew rates thereby increasing power efficiency.

FIG. 7 is a circuit diagram of a cascode circuit 400, in accordance with some embodiments.

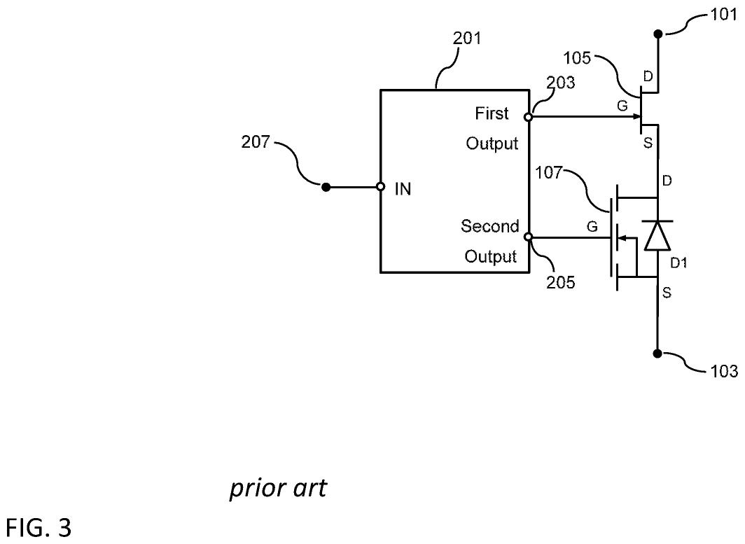

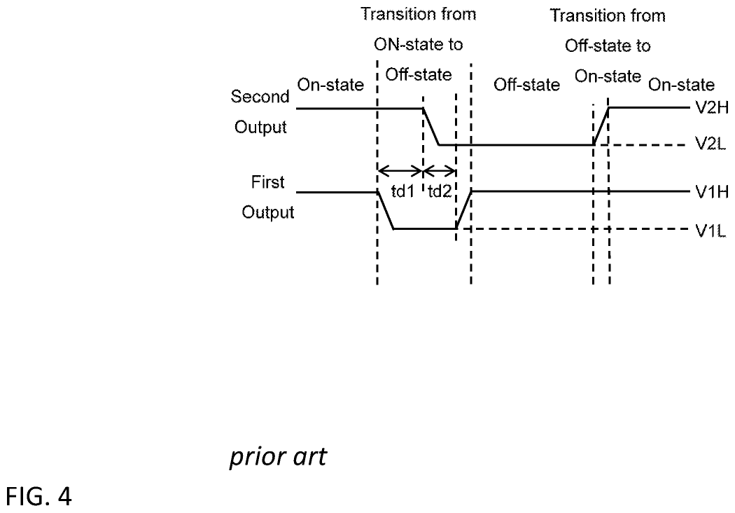

The cascode circuit 400 includes the JFET J1, the MOSFET M1, the connection terminal 302, the connection terminal 304, the control terminal 306, the gate return terminal 308, as described above with respect to FIG. 3. A driver circuit 412 is provided that generates the gate signal LVMOS, as described above with respect to FIG. 3. However, in this embodiment, the cascode circuit 400 does not include the rate-control device 310, 314. Instead, the cascode circuit 400 include a clamp switch 402, a turn-on control device 404, and a turn-off control device 406.

The turn-on control device 404 is connected in series between the gate of the JFET J1 and the source of the MOSFET M1. The turn-off control device 406 is connected in series between the gate of the JFET J1 and the source of the MOSFET M1. The clamp switch 402 has a clamp terminal 420 connected to the gate of the JFET J1 and a clamp terminal 422 connected to the source of the MOSFET M1. The clamp switch 402 has a control terminal 424 that is configured to receive a clamp drive signal from the driver circuit 412. When the clamp switch 402 is turned on, charge is allowed to flow between the gate of the JFET J1 and the source of the MOSFET M1 through the clamp switch 402. When the clamp switch 402 is turned off, charge is blocked from flowing between the gate of the JFET J1 and the source of the MOSFET M1 through the clamp switch 402. When the clamp switch 402 is turned on, the clamp circuit 400 is in a free-wheeling diode mode as current can flow directly though the clamp switch 402. The turn-on control device 404 is configured to allow charge to flow from the source of the MOSFET M1 to the gate of the JFET J1 so that as to control how fast the cascode device 400 is turned on. The turn-off control device 406 is configured to allow charge to flow from the gate of the JFET J1 to the source of the MOSFET M1 so that as to control how fast the cascode device 400 is turned off.

In this embodiment, the clamp switch 402 include a MOSFET M2 and a MOSFET M3. The gate of the MOSFET M2 and the gate of the MOSFET M3 are both connected to the control terminal 424 in order to receive the clamp drive signal. The clamp terminal 420 is the drain of the MOSFET M2. The source of the MOSFET M2 is connected to a drain of the MOSFET M3. The clamp terminal 422 is the source of the MOSFET M3. Thus, the clamp switch 402 is turned off in response to the clamp drive signal being in a low voltage state. The clamp switch 402 is turned on in response to the clamp drive signal being in a high voltage state.

The turn-on and turn-off control devices 404, 406 may be formed from various combinations of one or more resistors, diodes, and/or transistors, for example. The turn-on and turn-off control devices 404, 406 are configured to slow down the charging and discharging of the gate of the JFET J1, thereby controlling how fast the cascode device 400 is turned on and turned off. A diode D1 has an anode connected to the source of the MOSFET M1 and a cathode connected to the drain of the MOSFET M1. The voltage that can build up at the source of the JFET J1 and the drain of the MOSFET M1 is determined by the turn-on voltage of the diode D1 of the MOSFET. The clamp switch 402, the turn-on control device 404, and the turn-off control device 406 are utilized to control how fast the cascode circuit 400 is turned on and turned off. When the clamp switch 402 is turned off, how fast the cascode circuit 400 is turned off is determined by the charging rate through the turn-off device 406. This is when the turn off speed of the cascode circuit 400 is at its slowest. When the clamp switch 402 is turned off, how fast the cascode circuit 400 is turned on is determined by the charging rate through the turn-on device 404. This is when the turn on speed of the cascode circuit 400 is at its slowest. The clamp switch 402 is turned off in response to the clamp drive signal being in a low voltage state.

When the clamp switch 402 is turned on, the turn-on control device 404 and the turn-off control device 406 are bypassed through the clamp switch 402. Accordingly, the cascode circuit 400 is operating in the third quadrant (freewheeling diode mode). In the example of FIG. 7, both the turn-on control device 404 and the turn-off control device 406 are bypassed by the MOSFETs M2, M3 being turned on in response to when the clamp drive signal being in a high voltage state. When the claim clamp switch 402 is turned on, the turn off speed and the turn on speed of the cascode circuit 400 is at its fastest. As such, by controlling when the clamp switch 402 is turned on and turned off, the turn on speed and the turn off speed of the cascode circuit 400 is controlled.

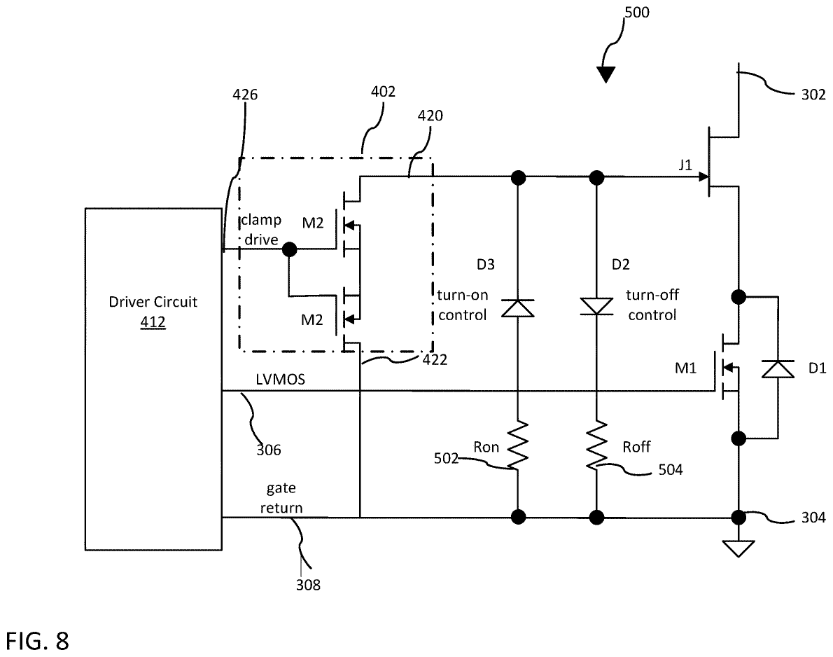

FIG. 8 is a circuit diagram of a cascode circuit 500, in accordance with some embodiments.

The cascode circuit 500 is the same as the cascode circuit 400 in FIG. 7, except that the cascode circuit 500 shows a specific embodiment for a turn on control device D3 and a specific embodiment for a turn off control device D2. Furthermore, the cascode circuit 500 includes resistors 502, 504. In this embodiment, the turn on control device D3 is a diode having a cathode connected to the gate of the JFET J1. An anode of the turn on control device D3 is connected to one end of the resistor 502. The other end of the resistor 502 is connected to the source of the MOSFET M1. The resistor 502 has a resistance Ron. The resistor 502 also determines a charging rate from the source of the MOSFET M1 to the gate of the JFET J1 and therefore also determines a turn on speed of the cascode circuit 500.

In this embodiment, the turn off control device D2 is a diode having an anode connected to the gate of the JFET J1. A cathode of the turn off control device D2 is connected to one end of the resistor 504. The other end of the resistor 504 is connected to the source of the MOSFET M1. The resistor 504 has a resistance Roff. The resistor 504 also determines a charging rate from the gate of the JFET J1 to the source of the MOSFET M1 and therefore also determines a turn off speed of the cascode circuit 500.

The turn on control device D3, the turn off control device D2, and the resistors 502, 504 are bypassed when the clamp switch 402 is turned on. Again, the clamp switch 402 is turned on in response to the clamp switch 402 being in a high voltage state (e.g., coincides with when the cascode is operating in the third quadrant/freewheeling diode mode).

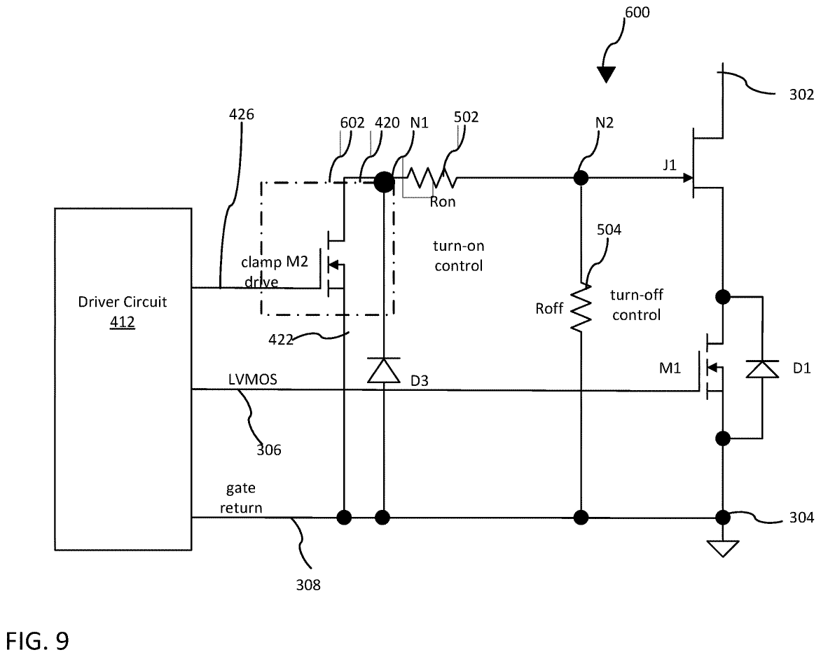

FIG. 9 is a circuit diagram of a cascode circuit 600, in accordance with some embodiments.

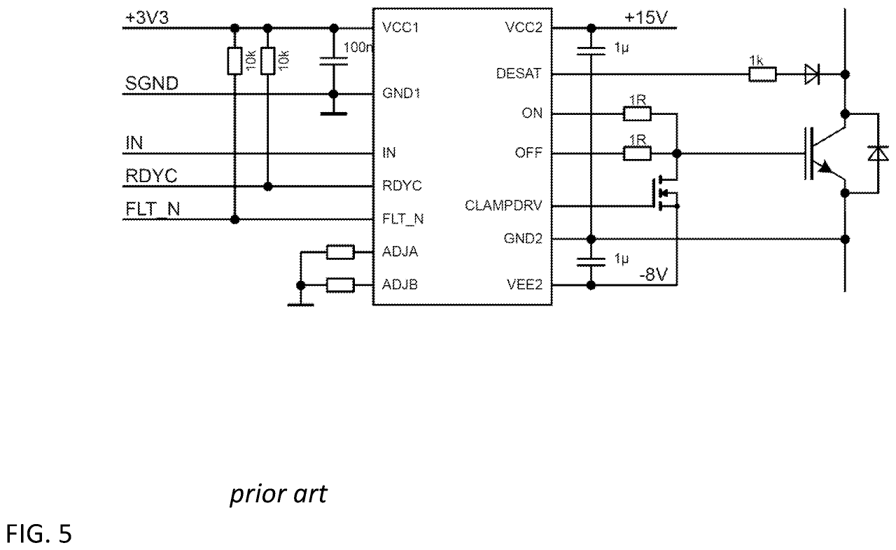

The cascode circuit 600 includes the JFET J1, the MOSFET M1, the connection terminal 302, the connection terminal 304, the control terminal 306, the gate return terminal 308, the driver circuit 412, and the diode D1 as described above with respect to FIG. 5. Furthermore, the turn-on control device D3 is provided. However, unlike the cascode circuit 500 in FIG. 8, the turn-on control device D3 has an anode connected to the source of the MOSFET M1 and a cathode connected to a node N1. Furthermore, in this embodiment, a clamp switch 602 only includes the MOSFET M2 and does not include the MOSFET M3. In this case, the drain of the MOSFET M2 is the clamp terminal 420 and the source of the MOSFET M2 is the clamp terminal 422. The clamp terminal 420 is connected to the node N1. Furthermore, the turn-off control device is not the diode D2. Instead, the turn off control device is provided as the resistor 504, which has one end connected to a node N2 and the opposite end connected to the source of the MOSFET M1. The resistor 502 is connected between the node N1 and the node N2. The node N1 is connected to the clamp terminal 420 and to the anode of the turn-on control device D3. In some embodiments, the turn-on control device D3 is simply provided as the body diode of the MOSFET M2. The node N2 is connected to one end of the resistor 504 and to the gate of the JFET J1.

When the cascode circuit 600 is being turned off and the clamp switch 602 is turned off in response to the clamp drive signal being in a low voltage state, the turn off speed of the cascode circuit 600 is determined by the resistor 504. When the cascode circuit 600 is being turned on and the clamp switch 602 is turned off in response to the clamp drive signal being in a low voltage state, the turn on speed of the cascode circuit 600 is determined by the diode D3 and the resistor 502 and the resistor 504. When the cascode circuit 600 is being turned on and the clamp switch 602 is turned on in response to the clamp drive signal being in a high voltage state, the turn on speed of the cascode circuit 600 is determined by the parallel connection of the resistor 502 and the resistor 504. When the cascode circuit 600 is being turned off and the clamp switch 602 is turned on in response to the clamp drive signal being in a high voltage state, the turn off speed of the cascode circuit 600 is determined by the parallel connection of the resistor 502 and the resistor 504. Accordingly, the turn on and turn off speed of the cascode circuit is controlled by the clamp switch 602.

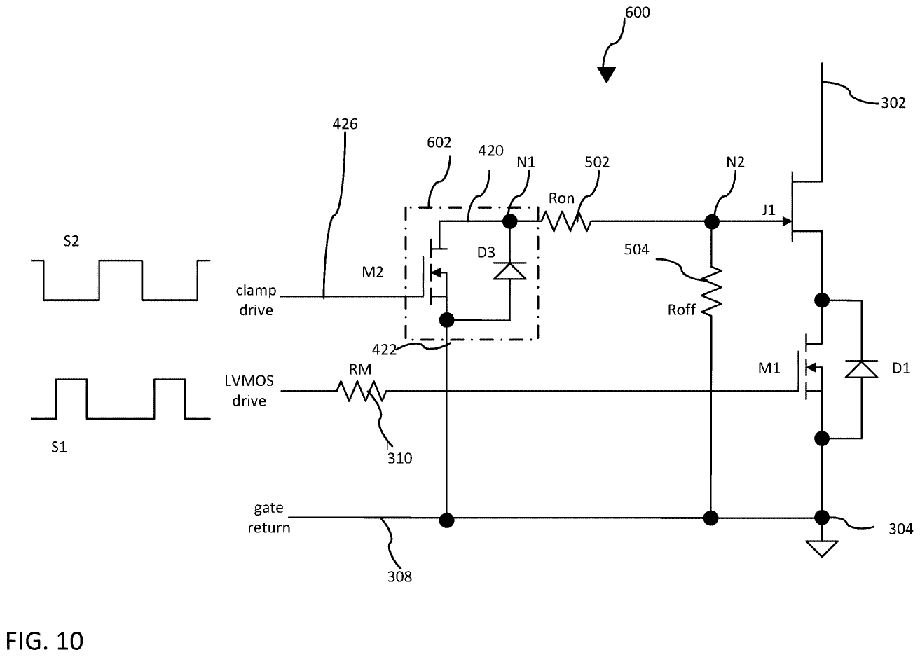

FIG. 10 shows the cascode circuit 600 of FIG. 9 along with waveforms for the gate signal (shown as S1 in FIG. 10) and waveforms for the clamp drive signal (shown as S2 in FIG. 10), in accordance with some embodiments.

As explained above, when the cascode circuit 600 is being turned on and the clamp switch 602 is turned off in response to the clamp drive signal being in a low voltage state, the turn on speed of the cascode circuit 600 is determined by the diode D3 and the resistor 502 and the resistor 504. When the cascode circuit 600 is being turned on and the clamp switch 602 is turned on in response to the clamp drive signal being in a high voltage state, the turn on speed of the cascode circuit 600 is determined by the parallel connection of the resistor 502 and the resistor 504. When the cascode circuit 600 is being turned off and the clamp switch 602 is turned on in response to the clamp drive signal being in a high voltage state, the turn off speed of the cascode circuit 600 is determined by the parallel connection of the resistor 502 and the resistor 504. Accordingly, the turn on and turn off speed of the cascode circuit is controlled by the clamp switch 602. As such, the phase differences between the positive and negative edges of the clamp drive signal and the gate signal LVMOS determine the turn on and turn off speeds of the cascode circuit 600. In addition, the duty cycles of the clamp drive signal and the gate signal LVMOS determine the turn on and turn off speeds of the cascode circuit 600. In alternative embodiments, rate-control devices may include transistors or combinations of transistors and resistors and other devices. Diode D1 of FIG. 10 may be the body diode of the MOSFET M1. Diode D3 may be the body diode of MOSFET M2.

The driver circuit 312 is a standard IGBT driver chip, in accordance with some embodiments. In some embodiments, the driver circuit 312 is configured to generate the clamp drive signal in a high voltage state whenever the gate signal to the MOSFET gate is off. Therefore, rate-control devices D3, 502, 504 may be used to control the switching speed of the JFET J1 and hence the switching speed of the cascode circuit 600.

When clamp switch 402 is on to provide freewheeling operation, the diode recovery is reduced. When the clamp switch 402 is off, the body diode D3 provides a path through the resistor 502 to control the turn-on speed. In alternative embodiments, one or more of the rate-control devices D3, 502, 504 are omitted.

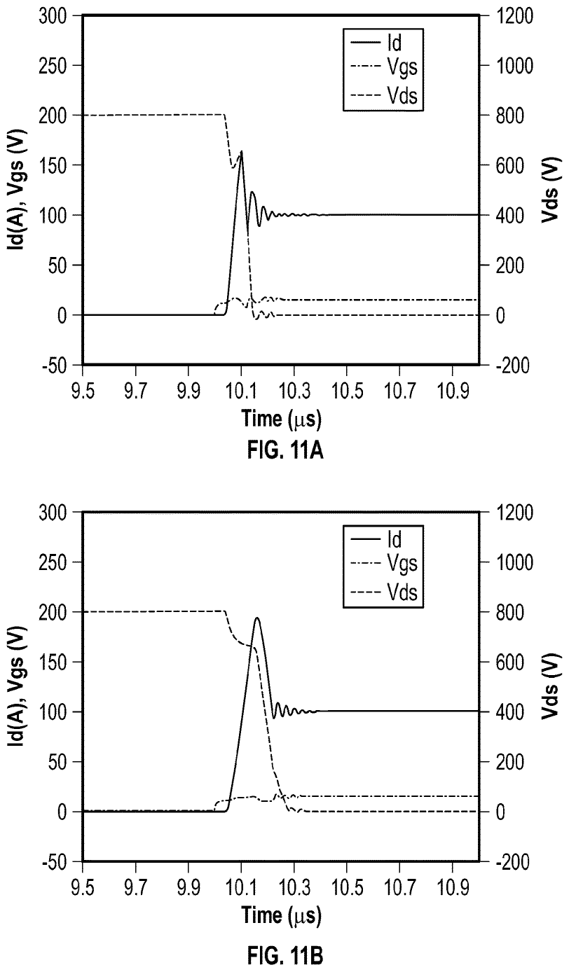

FIG. 11A illustrates a current and voltage graph versus time of the cascode circuit 600 in FIG. 10, in accordance with some embodiments. FIG. 11B illustrates a current and voltage graph versus time of the cascode circuit 300 in FIG. 6, in accordance with some embodiments.

By comparing FIG. 11A and FIG. 11B one can determine the reduction in return losses when using the clamp switch 602 versus when no clamping circuit is used as in FIG. 3. FIG. 11A illustrates the current from the connection terminal 302 to the connection terminal 304 (Id), the voltage between the control terminal 306 and the connection terminal 304 (Vgs), and the voltage between the connection terminal 302 and the connection terminal 304 of the cascode circuit 600, in accordance with some embodiments. FIG. 11B illustrates the current from the connection terminal 302 to the connection terminal 304 (Id), the voltage between the control terminal 306 and the connection terminal 304 (Vgs), and the voltage between the connection terminal 302 and the connection terminal 304 of the cascode circuit 300, in accordance with some embodiments. Both cascode circuits 300, 600 are turned on from 9.5 microseconds to approximately 10.3 microseconds, and then cascode circuits 300, 600 stay on.

As illustrated by FIG. 11A and FIG. 11B, the voltage spikes resulting from the transition are lower in the cascode circuit 600 when compared to the voltage spikes of the cascode circuit 300. As a result, the use of the clamp switch 602 increases the power efficiency of the cascode circuit 600 in comparison to the cascode circuit 300, in accordance with some embodiments.

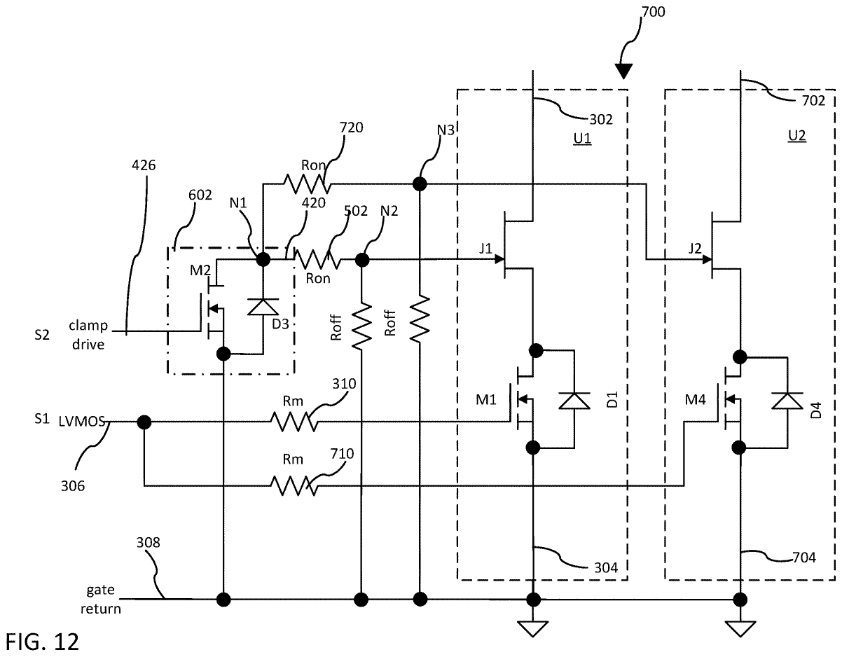

FIG. 12 is an embodiment of a cascode circuit 700 in accordance with some embodiments.

The cascode circuit 700 includes the JFET J1, the MOSFET M1, the connection terminal 302, the connection terminal 304, the control terminal 306, the gate return terminal 308, the diode D1, the turn-on control device D3 the node N1, the node N2, the clamp switch 602, the resistor 502, and the resistor 504, as described above with respect to FIG. 6. The JFET J1, the MOSFET M1, the connection terminal 302, the connection terminal 304, the control terminal 306 are provided in what is referred to as a cascode device U1. Furthermore, the cascode circuit 700 includes the resistor 310 that is connected between the control terminal 306 and the gate terminal of the MOSFET M1.

In addition, the cascode circuit 700 has another cascode device U2. The cascode device U2 has a JFET J2, a MOSFET M4, a diode D4, a connection terminal 702, a connection terminal 704. The JFET J2, the MOSFET M4, the diode D4, the connection terminal 702, the connection terminal 704 in the cascode device U2 are arranged in the same manner as the JFET J1, the MOSFET M1, the diode D1, the connection terminal 302, and the connection terminal 304 as described in FIG. 10. A resistor 710 is connected in series between the control terminal 306 and the gate of the MOSFET M4. The resistor 710 has a resistance of Rm. A resistor 720 is connected between the node N1 and a node N3. The resistor 720 has a resistance of Ron. A resistor 444 is connected between the node N3 and the source of the MOSFET M4. The resistor 444 has a resistance of Roff. The source of the MOSFET M4 is connected to the source of the MOSFET M1. The node N3 is connected to the gate of the JFET J2. This scheme allows a single drive circuit (not explicitly shown in FIG. 12 but is similar to the drive circuit in FIG. 10) to manage conduction through multiple paralleled cascode devices U1, J2, allowing the cascode circuit 700 to handle much higher currents. In alternative embodiments, a separate clamp switch is used for each gate of the JFETs J1, J2. Note that individual turn-on and turn-off resistors 502, 720, 310, 710 are used.

### Packaging Options

Dual gated cascode circuits with JFET clamps may be packaged in a variety of ways. For example, JFETs, such as Sic JFETs, and MOSFETs, such as silicon MOSFETs, may be mounted in separate discrete packages, e.g., using package formats such as TO247. The FETs of the cascode circuit may also be co-packaged. For example, a smaller MOSFET may be mounted directly (“stacked”) atop a larger JFET, and the resulting chip stack may be mounted in a TO247 package, D2PAK-7L, TOLL, Top Cool, or any other package. When co-packaged, the gates of the JFET and MOSFET may be brought out of the package separately, e.g., using a TO247-4L four-leaded package. Similarly, rate-control and other driver components may be co-packaged with cascode FETs. For example, a chip that provides a driver circuit may be packaged with a cascode device or multiple cascode devices. Additionally, multiple driver chips may be packaged with multiple cascode devices, for example, to produce power circuits such as inverters.

It will be appreciated that the techniques described herein may be applied to a variety of devices operating in a cascode modes. For example, a depletion mode FET other than a JFET may be utilized in some embodiments. Additionally, an enhancement mode FET other than a MOSFET may be used. It is merely in the interest of brevity that the example of cascode circuit including silicon carbide JFETs and silicon MOSFETs has be described throughout.

Standard SiC MOSFET and IGBT driver integrated circuits with Miller clamp drive outputs, such as those used for inverter applications, may be repurposed for use in cascode circuits to operate a clamp device connected to the gate of the high voltage transistor of the cascode pair. For example, in a cascode with a normally-on JFET and a gating MOSFET, the gate signal of the driver may be used to operate the MOSFET, and the clamp drive of the driver may be used to operate a switch connecting the gate of the JFET to the source of the cascode. This provides a cascode with both extremely low-on resistance and good control of switching characteristics.

If the gate of the MOSFET and JFET are provided separately, the composite device can be more easily slowed by adding a resistor between MOSFET source and JFET gate, for example. This controllability becomes more critical in high current applications, such as when paralleling many devices as in high current inverters. Thus, introducing a resistor between JFET gate and source of the MOSFET may be useful in slowing turn-off of the cascode.

We claim:

1. A cascode circuit, comprising:
a junction field-effect transistor, JFET, comprising a JFET drain, a JFET source, and a JFET gate, the JFET drain being connected to a drain of the cascode circuit, wherein the JFET is a normally-on n-type silicon carbide JFET;
a metal-oxide-semiconductor field-effect transistor, MOSFET, comprising a MOSFET drain, a MOSFET source, and a MOSFET gate, the MOSFET drain being connected to the JFET source and the MOSFET source being connected to a source of the cascode circuit, wherein the MOSFET is a normally-off n-type silicon MOSFET;
a driver circuit providing outputs comprising a first cascode gate signal and a clamp signal, the first cascode gate signal and the clamp signal being complementary waveforms, wherein the first cascode gate signal is connected to the MOSFET gate; and
a clamp switch controlled by the clamp signal, wherein the clamp switch, when activated, connects the JFET gate to the source of the cascode circuit;
whereby in a first mode the first cascode gate signal causes the MOSFET to conduct and current flows from the drain of the cascode circuit to the source of the cascode circuit via the JFET and the MOSFET while the clamp switch is off, and
in a second mode, the clamp signal causes the clamp switch to connect the JFET gate to the MOSFET source when the first cascode gate signal is on.

2. The cascode circuit of claim 1, wherein the first cascode gate signal is connected directly to the MOSFET gate.

3. The cascode circuit of claim 1, wherein a first rate-control device connects the JFET gate to the source of the cascode circuit.

4. The cascode circuit of claim 3, wherein the first rate-control device comprises a first resistor.

5. The cascode circuit of claim 3, wherein the first rate-control device comprises a first transistor.

6. The cascode circuit of claim 3, wherein the clamp switch is connected to the JFET gate via a second rate-control device.

7. The cascode circuit of claim 6, wherein the second rate-control device comprises a second resistor.

8. The cascode circuit of claim 6, wherein the second rate-control device comprises a second transistor.

9. The cascode circuit of claim 1, wherein the driver circuit further provides a second cascode gate signal, the second cascode gate signal being connected to the JFET gate.

10. The cascode circuit of claim 9, wherein the second cascode gate signal is connected to the MOSFET gate via a third rate-control device.

11. A cascode circuit, comprising:
a junction field-effect transistor, JFET, comprising a JFET drain, a JFET source, and a JFET gate, the JFET drain being connected to a drain of the cascode circuit, wherein the JFET is a normally-on n-type silicon carbide JFET;
a metal-oxide-semiconductor field-effect transistor, MOSFET, comprising a MOSFET drain, a MOSFET source, and a MOSFET gate, the MOSFET drain being connected to the JFET source and the MOSFET source being connected to a source of the cascode circuit, wherein the MOSFET is a normally-off n-type silicon MOSFET;
connectors receiving driver circuit outputs comprising a first cascode gate signal and a clamp signal, the first cascode gate signal and the clamp signal being complementary waveforms, wherein the first cascode gate signal is connected to the MOSFET gate; and
a clamp switch controlled by the clamp signal, wherein the clamp switch, when activated, connects the JFET gate to the source of the cascode circuit;
whereby in a first mode the first cascode gate signal causes the MOSFET to conduct and current flows from the drain of the cascode circuit to the source of the cascode circuit via the JFET and the MOSFET while the clamp switch is off, and
in a second mode, the clamp signal causes the clamp switch to turn on and short the JFET gate to the MOSFET source.

12. The cascode circuit of claim 11, wherein the first cascode gate signal is connected directly to the MOSFET gate.

13. The cascode circuit of claim 11, wherein a first rate-control device connects the JFET gate to the source of the cascode circuit.

14. The cascode circuit of claim 13, wherein the first rate-control device comprises a first resistor.

15. The cascode circuit of claim 13, wherein the first rate-control device comprises a first transistor.

16. The cascode circuit of claim 13, wherein the clamp switch is connected to the JFET gate via a second rate-control device.

17. The cascode circuit of claim 16, wherein the second rate-control device comprises a second resistor.

18. The cascode circuit of claim 16, wherein the second rate-control device comprises a second transistor.

19. The cascode circuit of claim 11, wherein the driver circuit outputs further provide a second cascode gate signal, the second cascode gate signal being connected to the JFET gate.

20. A cascode circuit, comprising:
a depletion mode field-effect transistor (FET) having a first drain, a first source, and a first gate;
an enhancement mode FET having a second drain, a second source, and a second gate, wherein the first source is connected to the second drain; and
a clamping device having a first clamping terminal connected to the first gate and a second clamping terminal connected to the second source.
